(19) United States
(12) Patent Application Publication
(10) Pub. No.: US 2002/0036343 A1
(43) Pub. Date: Mar. 28, 2002

(54) Semiconductor fabrication device and method for preventing the attachment of extraneous particles

(75) Inventors: Tsuyoshi Moriya, Tokyo (JP); Natsuko Ito, Tokyo (JP); Fumihiko Uesugi, Tokyo (JP)

Correspondence Address: SUGHRUE, MION, ZINN, MACPEAK & SEAS, 2100 Pennsylvania Avenue, N.W., Washington, DC, 20037-3202, US

(73) Assignee: NEC CORPORATION

(21) Appl. No.: 09/950,759

(22) Filed: Sep. 13, 2001

(30) Foreign Application Priority Data
Sep. 25, 2000 (JP) 2000-290632

(51) Int. Cl. H01L 21/302; H01L 21/461; H01L 23/34

(52) U.S. Cl. 257/717

(57) ABSTRACT

A semiconductor fabrication device includes a processing chamber in which the interior is substantially sealed. An upper processing electrode and a lower processing electrode are provided inside the processing chamber, and a stage made from a material having high thermal conductivity and on which semiconductor substrate is mounted is provided above the lower processing electrode. In this semiconductor fabrication device, for example, processing gas is introduced into the processing chamber, a radio-frequency voltage is applied between the two electrodes to generate plasma, and a process of etching a deposited film on the semiconductor substrate is carried out. While the process is being carried out, the semiconductor substrate is cooled by causing a cooling medium to flow but without allowing the cooling medium to pass through the processing chamber and thus without causing extraneous particles to occur in the processing chamber.

### BACKGROUND OF THE INVENTION

1. Field of the Invention

The present invention relates to a semiconductor fabrication device and semiconductor fabrication method, and more particularly to a semiconductor fabrication device having the capability of preventing degradation of product quality due to extraneous particles that occur inside the semiconductor fabrication device during the fabrication process (referred to hereinbelow as “particles”) that become attached to the substrate that undergoes processing.

2. Description of the Related Art

In the fabrication steps of LSI, particles that occur inside a semiconductor fabrication device is a major factor in both decreasing product yield and decreasing the serviceability ratio of the semiconductor fabrication device as a result of the particle attaching itself to the substrate that is undergoing processing and so on. Such particles are produced as a result of, for example, peeling off of reaction products (deposited films) that adhere to the inside of the semiconductor fabrication device or growing of reaction products in plasma. Methods such as attaching a cover to cover the processed substrate after processing have been proposed for preventing these types of particles from falling onto the substrate that undergoes processing, as disclosed in, for example, Japanese Patent Application Laid-open No. 29272/93 and Japanese Patent Application Laid-open No. 58033/95.

FIG. 1 shows a schematic sectional view of a typical semiconductor fabrication device of the prior art. This semiconductor fabrication device includes processing chamber 107 in which semiconductor substrate 101 that is to be processed can be mounted by way of gate valve 109. Processing chamber 107 is provided with introduction port 110 for introducing processing gas such as etching gas and evacuation port 111 for evacuating the interior of processing chamber 107. The introduction path of the processing gas leads from introduction port 110 to showerhead 106. Showerhead 106 is positioned over the surface of semiconductor substrate 101 that should be processed and includes a large number of openings that range over the surface to be processed. This configuration enables substantially uniform application of the processing gas to the surface to be processed.

In addition, upper processing electrode 102 and lower processing electrode 103 are provided in the upper and lower portions of processing chamber 107 for supplying a radio-frequency power to the interior of processing chamber 107. RF generator 104 is connected to lower processing electrode 103, and upper processing electrode 102 is grounded. Stage 105, upon which semiconductor substrate 101 is mounted, is provided on lower processing electrode 103 with insulator 108 interposed between stage 105 and lower processing electrode 103. An electrostatic chuck power supply (not shown in the figure) is connected to stage 105, whereby stage 105 functions as an electrostatic chuck electrode that secures semiconductor substrate 101 by electrostatic force. Stage 105 is capable of moving up and down to place semiconductor substrate 101 at the vertical position that is appropriate for processing.

In addition, cooling medium gas passage 112 is formed so as to pass through stage 105, insulator 108, and lower processing electrode 103 to introduce a cooling medium gas for cooling semiconductor substrate 101 during processing. Cooling medium gas passage 112 includes a plurality of openings directly below semiconductor substrate 101.

The processing of semiconductor substrate 101 by means of this semiconductor fabrication device is performed by introducing processing gas from introduction port 110 and supplying radio-frequency power to the interior of processing chamber 107 by way of upper processing electrode 102 and lower processing electrode 103. During this time, semiconductor substrate 101 is cooled in order to keep semiconductor substrate 101 at the temperature that is appropriate for processing and so on. This cooling is realized by directing, under high pressure, a cooling medium gas having good thermal conductivity such as helium gas against the lower surface of semiconductor substrate 101.

In this semiconductor fabrication device of the prior art, the cooling medium gas that is directed under high pressure is discharged inside processing chamber 107 from the periphery of semiconductor substrate 101 and discharged from evacuation port 111 together with the processing gas. A major defect of the prior-art semiconductor device is that the cooling medium gas may at this time dislodge deposited films that have been applied to the periphery of semiconductor substrate 101 or extraneous matter that is present around the periphery of semiconductor substrate 101. In other words, there is the danger that particles that are dislodged in this way may land on and become attached to semiconductor substrate 101 during processing and damage the characteristics of semiconductor substrate 101.

### SUMMARY OF THE INVENTION

It is an object of the present invention to provide a novel semiconductor fabrication device and semiconductor fabrication method that solve this defect of the prior art, i.e., that can prevent the occurrence of particles inside the processing chamber, or, if particles have occurred, that can prevent the particles from reaching the semiconductor substrate.

A semiconductor fabrication device in which the present invention is applied includes a processing chamber that can be substantially sealed so as to keep the interior clean. A stage, upon which the semiconductor substrate that is the object of processing is mounted, is provided inside this processing chamber. During processing, the semiconductor substrate is cooled.

According to an embodiment of the semiconductor fabrication device of the present invention, the stage is constituted from a material having high thermal conductivity. A cooling medium passage is provided for conducting the cooling medium that cools the stage only outside the processing chamber. Thus, the cooling medium gas is not discharged inside the processing chamber, and the semiconductor substrate can be effectively cooled while suppressing the occurrence of particles that accompanies the introduction of the cooling medium gas.

Diamond is particularly suitable as the material having high thermal conductivity that is used for the stage.

In addition, a suction passage having openings in the area of the stage that directly underlies the semiconductor substrate when the semiconductor substrate is mounted may be provided to hold the semiconductor substrate onto the stage so that the semiconductor substrate is in closely contact with the stage. The suction passage is connected to a suction pump that is capable of reducing the internal pressure of the suction passage to a pressure that is lower than the internal pressure of the processing chamber during processing. In this way, heat can be effectively conducted from the semiconductor substrate and to the stage. This method of securing the semiconductor substrate by suction is effective as a securing method that can substitute for electrostatic chuck in cases in which the stage is composed of an insulative material and therefore cannot secure the semiconductor substrate by electrostatic chuck.

A semiconductor fabrication device according to embodiments of the present invention described hereinbelow includes a cooling medium gas passage having openings in the area of the stage that directly underlies the semiconductor substrate when the semiconductor substrate is mounted and into which cooling medium gas is introduced.

The second embodiment of the semiconductor fabrication device of the present invention includes a first evacuation passage having openings in the area of the stage that directly underlies the semiconductor substrate when the semiconductor substrate is mounted. According to this configuration, evacuation is realized during processing by means of an evacuation pump that is connected to the first evacuation passage, whereby the cooling medium gas that is discharged into the processing chamber from the periphery of the semiconductor substrate can be reduced and the occurrence of particles can be suppressed.

In this configuration, the openings of the first evacuation passage are preferably opened in a peripheral area of the area of the stage that directly underlies the semiconductor substrate, and the openings of the cooling medium gas passage are preferably opened in the central area that is surrounded by the peripheral area in which the openings of the first evacuation passage are opened. By means of this configuration, the discharge of cooling medium gas from the periphery of the semiconductor substrate can be almost entirely eliminated.

The third embodiment of the semiconductor fabrication device of the present invention includes a second evacuation passage having openings in a peripheral area of the area on the stage that directly underlies the semiconductor substrate when the semiconductor substrate is mounted. By means of this configuration, the flow of cooling medium gas that is discharged inside the processing chamber during processing can be directed downward from the periphery of the semiconductor substrate by evacuation that is realized by an evacuation pump that is connected to the second evacuation passage. Thus this configuration can prevent the flow of particles above the semiconductor substrate due to the flow of the cooling medium gas and can prevent particles from reaching the semiconductor substrate.

In the fourth embodiment of the semiconductor fabrication device of the present invention, the upper surface of the stage is smaller than the semiconductor substrate. By means of this configuration, virtually none of the cooling medium gas flows upward because cooling medium gas that is directed against the lower surface of the semiconductor substrate and discharged from the periphery of the semiconductor substrate inside the processing chamber collides with the portion of the lower surface of the semiconductor substrate that protrudes from the stage. Thus this configuration can prevent the flow of particles above the semiconductor substrate that is caused by the flow of the cooling medium gas and can prevent particles from reaching the semiconductor substrate.

The fifth embodiment of the semiconductor fabrication device of the present invention includes an introduction control means for introducing the cooling medium gas such that its flow rate does not exceed a prescribed flow rate. Suppressing the flow rate of the cooling medium gas to or below a prescribed flow level can prevent the flow of cooling medium gas from applying excessive force against deposited film that adheres to the vicinity of the semiconductor substrate or extraneous matter that is present in the vicinity of the semiconductor substrate, either of which can become particles, and thus can decrease the occurrence of particles inside the processing chamber.

A control means that controls flow rate may be suitably employed as the introduction control means.

The sixth embodiment of the semiconductor fabrication device of the present invention includes a processing gas introduction means for introducing processing gas into the processing chamber, and a lower processing electrode and upper processing electrode for supplying electrical power to convert the processing gas to plasma. The lower processing electrode is arranged in the lower portion of the processing chamber, and the stage is arranged over the lower processing electrode. The upper processing electrode is arranged in the upper portion inside the processing chamber so as to confront the lower processing electrode. An elimination electrode that is connected to a direct-current power supply is provided in the vicinity of the semiconductor substrate.

By means of this configuration, particles that have been charged under the influence of electrostatic potential that occurs with the generation of plasma can be attracted to the elimination electrode and removed. Charged particles in the vicinity of the substrate can be removed by giving the elimination electrode a negative charge. Particles that have been charged inside the bulk plasma can be removed by giving the elimination electrode a positive charge. A first elimination electrode that is given a negative charge and a second elimination electrode that is given a positive charge may also be provided.

The first semiconductor fabrication method of the present invention includes a step for giving a mirror-surface polishing treatment to the lower surface of the semiconductor substrate before mounting the semiconductor substrate on the stage. Providing a mirror surface on the lower surface of the semiconductor substrate can eliminate extraneous matter adhering to the lower surface of the semiconductor substrate that may become particles and can decrease the occurrence of particles inside the processing chamber. This semiconductor fabrication method that employs the semiconductor fabrication device of the first embodiment in particular enables an improvement in thermal conductivity from the semiconductor substrate to the stage.

The second semiconductor fabrication method of the present invention includes a step for cleaning the stage before mounting the semiconductor substrate on the stage. This cleaning eliminates extraneous matter adhering to the stage that may become particles and can reduce the occurrence of particles inside the processing chamber.

The third semiconductor fabrication method of the present invention includes a step for cleaning the lower surface of the semiconductor substrate before mounting the semiconductor substrate onto the stage. This cleaning can eliminate extraneous matter adhering to the lower surface of the semiconductor substrate that can become particles and can reduce the occurrence of particles inside the processing chamber.

The constitutions of the first to sixth embodiments of the semiconductor fabrication devices of the present invention and the first to third embodiments of the semiconductor fabrication method can be combined as appropriate, and this combination can obtain a synergistic improvement in the effect of suppressing the attachment of particles to a semiconductor substrate.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a schematic sectional view of a semiconductor fabrication device of the prior art;

FIG. 2 is a schematic structural view of a particle monitoring system that is used in observing particles inside semiconductor fabrication devices in embodiments of the present invention;

FIG. 3 is a graph showing the number of particles that occur inside the processing chamber and change in each of the process signals over time when carrying out prescribed processes on a semiconductor substrate in the processing chamber as observed by means of the particle monitoring system of FIG. 2;

FIG. 4 is an image of particles that are blown from the vicinity of a semiconductor substrate;

FIG. 5 is an image of a particle that has landed on a semiconductor substrate;

FIG. 6 is a schematic sectional view of a semiconductor fabrication device showing the basic concept of the first embodiment of the present invention;

FIG. 7 is a schematic sectional view of a semiconductor fabrication device showing an actual plan of the concept of the first embodiment of the present invention;

FIGS. 8a and 8b are side views of a portion of the stage of the semiconductor fabrication device showing another actual plan of the concept of the first embodiment of the present invention;

FIG. 9 is a schematic sectional view of a semiconductor fabrication device showing another actual plan of the concept of the first embodiment of the present invention;

FIG. 10 is a schematic sectional view of the semiconductor fabrication device according to the second embodiment of the present invention;

FIG. 11 is a schematic sectional view of a modification of the semiconductor fabrication device of FIG. 10;

FIG. 12 is a schematic sectional view of the semiconductor fabrication device of the third embodiment of the present invention;

FIG. 13 is a schematic sectional view of the semiconductor fabrication device of the fourth embodiment of the present invention;

FIG. 14 is a graph showing the change over time in the flow rate of the cooling medium gas when the cooling medium gas is introduced by means of the introduction method of the prior art for comparison with the introduction method of the fifth embodiment of the present invention;

FIG. 15 is a graph showing the change over time in the flow rate of the cooling medium gas when the cooling medium gas is introduced by means of the introduction method of the fifth embodiment of the present invention;

FIG. 16 is a schematic side view of the interior of the processing chamber of the semiconductor fabrication device of the sixth embodiment of the present invention;

FIG. 17a is a flow chart showing the procedure of the semiconductor fabrication method of the prior art;

FIG. 17b is a flow chart showing the procedure of the semiconductor fabrication method of the seventh embodiment of the present invention;

FIG. 18a is a flow chart showing the procedure of the semiconductor fabrication method of the prior art; and

FIG. 18b is a flow chart showing the procedure of the semiconductor fabrication method of the eighth embodiment of the present invention.

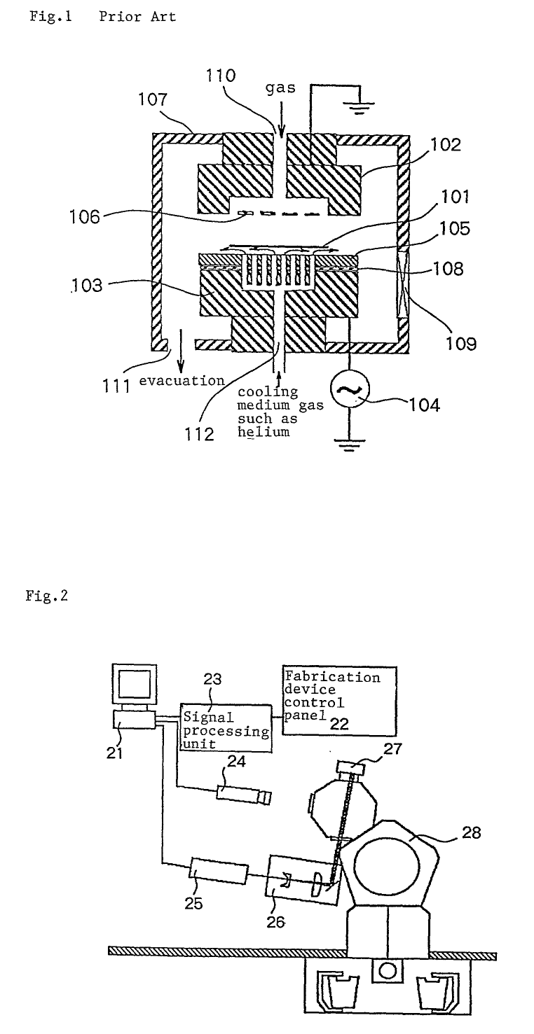

### DETAILED DESCRIPTION OF THE PREFERRED EMBODIMENTS

Semiconductor processing devices, and in particular, a semiconductor processing device that processes a semiconductor substrate by introducing a processing gas into a processing chamber in which a semiconductor substrate has been set while supplying radio-frequency electrical power to convert the processing gas to plasma, may require cooling of the semiconductor substrate during processing. The present invention is provided for preventing damage to the characteristics of a semiconductor substrate in this type of semiconductor fabrication device, this damage occurring when a cooling medium gas that is directed against a semiconductor substrate for the purpose of cooling stirs up deposited films that adhere to the periphery of the semiconductor substrate or extraneous matter that is present here and causes the resulting particles to become attached to the semiconductor substrate.

Referring now to FIGS. 2 through 5, an explanation is presented regarding the results of observing the occurrence of particles in the processing chamber of this type of semiconductor fabrication device and the behavior of the particles that occur.

FIG. 2 is a schematic structural view of a particle monitoring system that is used in the observation of the particles. The semiconductor fabrication device that is used in these observations includes the processing chamber 27 in which processing of the semiconductor substrate is carried out, and transfer chamber 28 for holding the semiconductor substrate that is sent into processing chamber 27. The particle monitoring system is a system that uses a laser scattering method. In this system, laser light is directed by way of optics 26 from laser light source 25 to processing chamber 27. The number of particles inside processing chamber 27 can be measured by using CCD camera 24 to detect the laser light that is scattered inside processing chamber 27. Control of laser light source 25 and the processing of the detection signals of CCD camera 24 are realized by computer 21. Computer 21 receives as input from semiconductor fabrication device control panel 22 by way of signal processing unit 23 signals indicating the states of the semiconductor fabrication process such as processing radio frequency power (RF Power), the internal pressure of the chamber (Pressure), the flow rate of the processing gas (sulfur hexafluoride: SF₆) (SF₆ flow rate), the degree of openness of a gate valve for conveying the semiconductor substrate (Isolation valve), the flow rate of the cooling helium gas (He flow rate), the electrostatic chuck voltage (ESC voltage), the electrostatic chuck current (ESC current), and the raised position of the stage (Stage up).

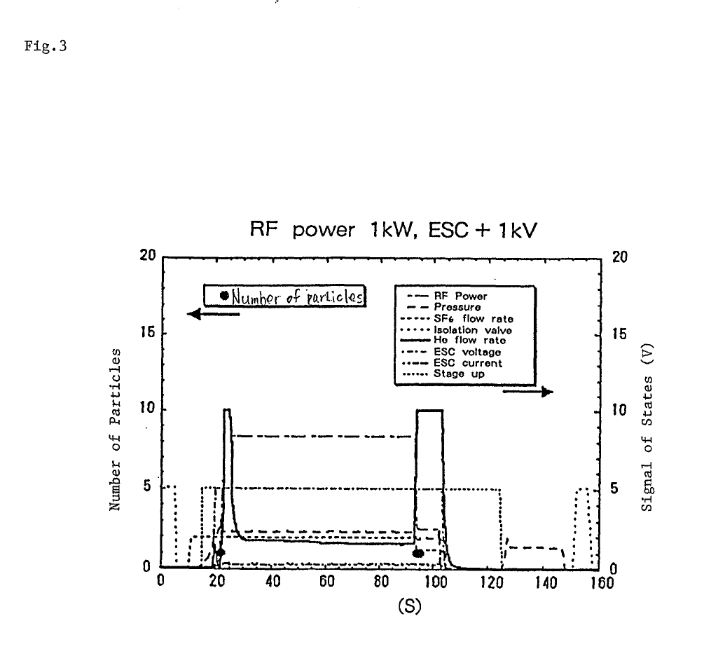

FIG. 3 shows the results of using this type of particle monitoring system to monitor the number of particles that occur in processing chamber 27 and changes in each of the processing signals when carrying out prescribed processes on a semiconductor substrate in processing chamber 27.

Helium gas for cooling is normally pressure controlled and introduced to maintain cooling of the semiconductor substrate at a definite level. The cooling helium gas therefore flows at a high rate when the gas is first introduced and until the pressure reaches a prescribed level, as shown in FIG. 3. When the processing conditions on the semiconductor substrate change, the cooling helium gas flows at a high rate if the suction force on the semiconductor substrate relative to the ambient pressure weakens and so on. In the example shown in FIG. 3, when the processing time reaches approximately 95 seconds, the level of supply of radio-frequency power and the rate of introduction of processing gas are reduced and the cooling helium gas flows at a high rate. As can be seen from FIG. 3, a large number of particles occur inside processing chamber 27 when the rate of flow of the helium gas becomes extremely high.

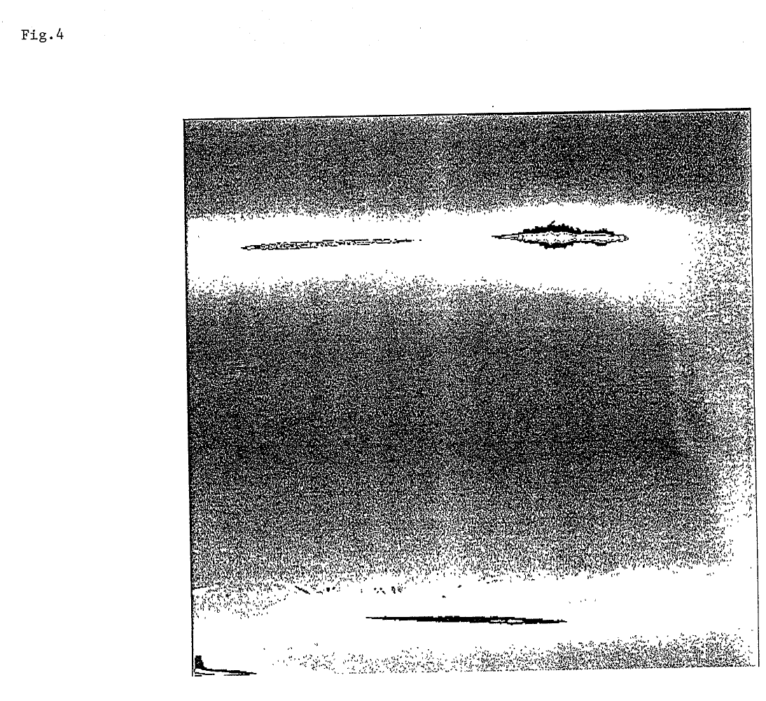

This fact suggests that the occurrence of particles inside processing chamber 27 is caused by the cooling helium gas. The occurrence of particles that are dislodged from the periphery of the semiconductor substrate can actually be captured as an image as shown in FIG. 4.

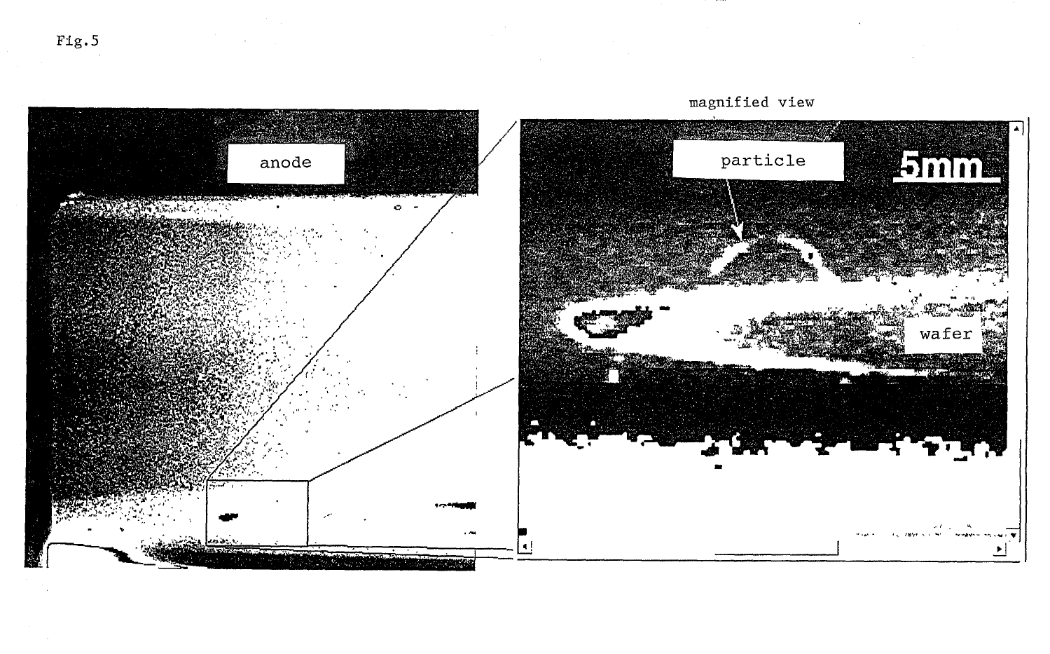

Particles that occur at the periphery of the semiconductor substrate in this way fly toward the semiconductor substrate in a parabolic line and lodge onto the semiconductor substrate. FIG. 5 shows an image that captures this movement of particles. This movement of the particles has been confirmed in a semiconductor fabrication device that uses plasma. It is believed that this movement of the particles is caused by the effect of electrostatic force. This point is further explained hereinbelow.

In a semiconductor fabrication device that employs plasma, the semiconductor substrate is normally mounted on the lower processing electrode, and a sheath is formed in the vicinity of the semiconductor substrate. Further, a cathode electrode is normally used as the lower processing electrode, and the electrostatic potential in the vicinity of the lower processing electrode is negative. Positive ions are therefore extremely numerous in the area of the cathode sheath in the vicinity of the semiconductor substrate, and the particles that are stirred up from the vicinity of the semiconductor substrate are positively charged by the inflow of positive ions in the area of this cathode sheath.

In contrast, a self-bias potential is spontaneously generated on the surface of the semiconductor substrate by the plasma that is generated by applying a radio-frequency voltage. In this configuration, this self-bias potential is a negative potential. Thus, particles that have been positively charged in the cathode sheath are attracted by the effect of the electrostatic force to the semiconductor substrate, which has a negative self-bias potential. It is believed that this attraction explains the previously described parabolic flight of particles toward the semiconductor substrate.

In addition, in a case in which the cooling medium gas stirs up particles with extremely great force, particles are stirred up and enter the bulk plasma that is generated above the cathode sheath. In contrast with the interior of the cathode sheath, negative ions and electrons exist in extremely large numbers inside the bulk plasma, and particles that enter the bulk plasma are therefore negatively charged and trapped in the bulk plasma. It is believed that virtually none of the particles that are trapped in this way fall onto the semiconductor substrate during processing of the semiconductor substrate, but some particles fall and become attached to the semiconductor substrate when the balance of forces is disrupted by changes in the processing conditions such as the radio-frequency power.

The present invention was arrived at based on information such as described hereinabove relating to the occurrence of particles inside the processing chamber of a semiconductor fabrication device and the behavior of particles that occur. The present invention makes the proposals described below.

First, because a large number of particles occur inside the processing chamber due to the cooling medium gas that is blown into the processing chamber from the periphery of the semiconductor substrate, the present invention proposes, as one method of preventing the attachment of particles to the semiconductor substrate, a cooling method for cooling the semiconductor substrate other than directing a cooling medium gas against the semiconductor substrate.

Specifically, in a semiconductor fabrication device that requires cooling of the semiconductor substrate, the present invention proposes a semiconductor fabrication device having a construction that allows cooling of the semiconductor substrate without blowing a cooling medium gas such as helium directly onto the semiconductor substrate by using a substance having high thermal conductivity such as diamond as the material of the semiconductor substrate stage. In this case, the cooling effect can be increased by giving the lower surface of the substrate a mirror-surface polishing treatment so as to improve the tightness of the contact with the stage.

The present invention further proposes, as a method of securing the semiconductor substrate in a case in which the semiconductor substrate cannot be secured by electrostatic force as in the prior art due to the use of a nonconductive substance such as diamond as the stage, a method of securing the semiconductor substrate by vacuum suction by evacuating air from a suction passage having openings in the upper surface of the stage at a position that directly contacts the lower surface of the semiconductor substrate. In this case, the suction force can be increased by giving the lower surface of the semiconductor substrate a mirror-surface polishing treatment.

The present invention further proposes, as another method of preventing attachment of particles to a semiconductor: a method for eliminating the blowing of cooling medium gas from the periphery of the semiconductor substrate, a method of decreasing the amount of cooling medium gas that is blown; and a method of preventing particles from being stirred up onto the semiconductor substrate by the cooling medium gas that is blown.

Specifically, the present invention proposes a method of preventing or decreasing the agitation of particles by varying the geometrical configuration inside the semiconductor fabrication device, strengthening the suction force on the semiconductor substrate, providing evacuation openings for the cooling medium gas, and devising methods of introducing the cooling medium gas.

The present invention also proposes, as another method of preventing the attachment of particles to a semiconductor, a method that takes advantage of the positive or negative charge of particles that are agitated and uses an electrode to which a bias potential is applied to eliminate particles.

The present invention further proposes, as another method of preventing the attachment of particles to a semiconductor, a method for eliminating deposited films or extraneous matter on the semiconductor substrate or on portions on which the semiconductor substrate is mounted before processing the semiconductor substrate.

Turning now to the figures, embodiments that exemplify these specific countermeasures are next explained.

Although explanation in the following embodiments refers to an RF plasma etching device unless clearly specified otherwise, the principal constitution is substantially equivalent for semiconductor fabrication devices such as CVD devices, etching devices, or sputtering devices, and the present invention can also be applied to these semiconductor fabrication devices.

(First Embodiment)

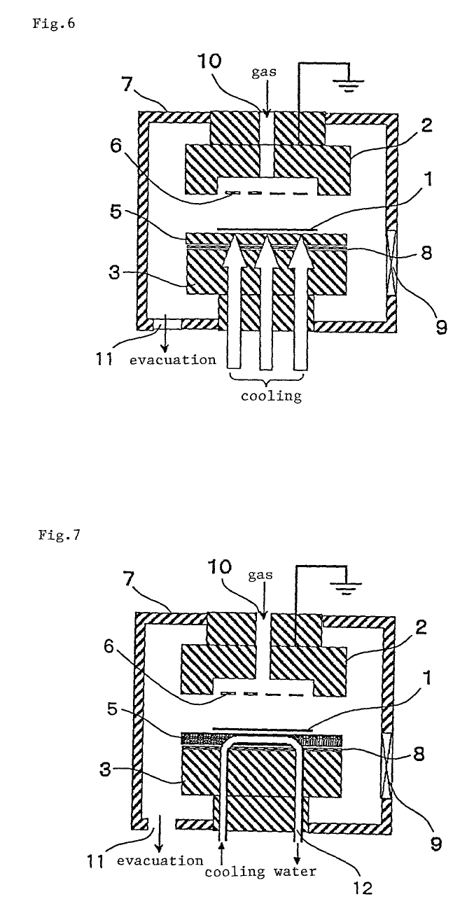

FIG. 6 shows a schematic sectional view of a semiconductor fabrication device that demonstrates the basic concept of the first embodiment of the present invention.

This semiconductor fabrication device includes processing chamber 7 that allows semiconductor substrate 1 that is the object of processing to be mounted inside by way of gate valve 9. Processing chamber 7 is provided with introduction port 10 for introducing processing gas such as etching gas and evacuation port 11 for evacuating the interior of processing chamber 7. The passage for the processing gas passes from introduction port 10 to showerhead 6. Showerhead 6 is positioned over the surface of semiconductor substrate 1 that is to be processed, and includes a multiplicity of openings over the surface that is to be processed. This construction allows a substantially uniform application of processing gas to the surface that is to be processed.

In addition, upper processing electrode 2 and lower processing electrode 3 are provided at the upper and lower portions inside processing chamber 7 for supplying radio-frequency power to the interior. An RF generator (not shown in the figure) is connected to lower processing electrode 3, and upper processing electrode 2 is grounded. Stage 5, on which semiconductor substrate 1 is mounted, is provided on lower processing electrode 3 with insulator 8 interposed between lower processing electrode 3 and stage 5. An electrostatic chuck power supply (not shown in the figure) is connected to stage 5, whereby stage 5 functions as an electrostatic chuck electrode that secures semiconductor substrate 1 by electrostatic force. Stage 5 is also capable of moving up and down to enable placement of semiconductor substrate 1 at the vertical position that is appropriate for processing.

When processing semiconductor substrate 1 in the semiconductor fabrication device of the present embodiment, semiconductor substrate 1 must be cooled for the purpose of establishing the temperature that is appropriate to the process and so on. If the cooling of semiconductor substrate 1 is implemented by using a method that raises the cooling effect of semiconductor substrate 1 by directing a cooling medium gas such as helium gas against semiconductor substrate 1 at high pressure and the gas is introduced such that it fills the gap between stage 5 and the lower surface of semiconductor substrate 1 as shown as the prior art, there is the problem that the cooling medium gas agitates particles, as described hereinabove.

In the present embodiment, however, the occurrence of particles can be prevented by employing a cooling method that can cool semiconductor substrate 1 without introducing a cooling medium gas into processing chamber 7.

In principle, any method that does not agitate particles may be adopted as the cooling method used in this embodiment. As a specific example, one method involves using a material having high thermal conductivity as the material of stage 5 on which semiconductor substrate 1 is mounted, providing cooling medium passage 12 that passes at least through the area inside stage 5 that directly underlies semiconductor substrate 1 as shown in FIG. 7, and causing a cooling medium such as coolant water to flow through this passage. By adopting this form, the heat of semiconductor substrate 1 is transmitted to stage 5, which is cooled, thereby enabling the rapid cooling of semiconductor substrate 1. In this method, the occurrence of particles inside processing chamber 7 can be reduced because a cooling medium gas is not introduced into processing chamber 7.

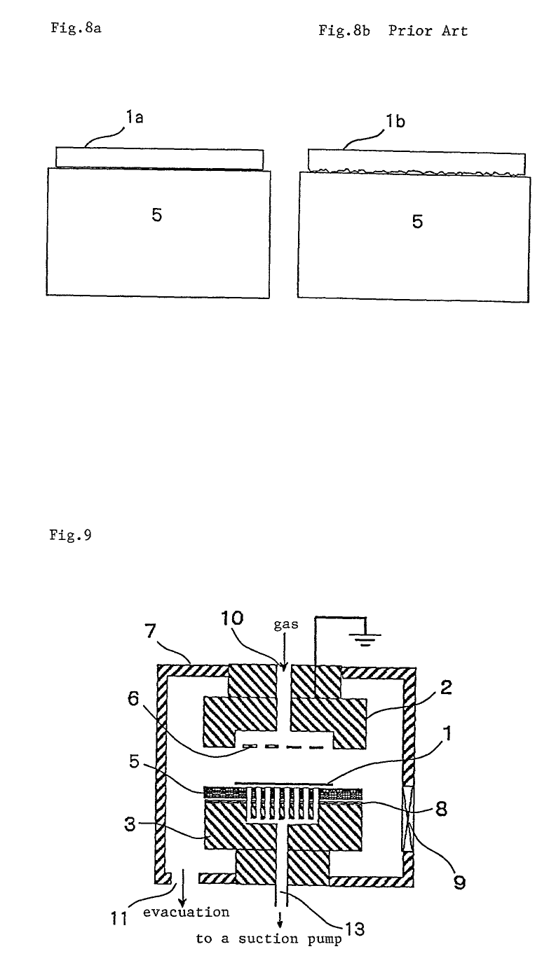

In a case in which semiconductor substrate 1 is cooled by letting heat escape from semiconductor substrate 1 to stage 5, close contact is preferably established between semiconductor substrate 1 and stage 5 so as to effectively transmit the heat and improve the cooling effect. FIGS. 8a and 8b are side views of the vicinity of stage 5 for explaining this point.

As shown in FIG. 8b, the lower surface of semiconductor substrate 1b is normally rough and has some unevenness. When unevenness exists, the area of contact between semiconductor substrate 1b and stage 5 is small and the amount of heat that is directly transmitted by this contact is limited. Heat is transmitted only indirectly in the portions in which gaps between semiconductor substrate 1b and stage 5 occur due to this unevenness, and in these portions the thermal conductivity from semiconductor substrate 1b to stage 5 is low. Due to these circumstances, the surface of semiconductor substrate 1b tends to gradually heat up in accordance with the processing conditions. However, the use of semiconductor substrate 1a having a lower surface that has been polished to a mirror state as shown in FIG. 8a enables an increase in the degree of close contact between stage 5 and semiconductor substrate 1a, an increase in the area of contact, and an improvement of the thermal conductivity from semiconductor substrate 1a to stage 5.

Alternatively, a deformable material such as rubber may be used as the material of at least the surface of stage 5 to increase the area of contact between semiconductor substrate 1 and stage 5. In other words, the use of this type of material in stage 5 allows stage 5 to conform to the unevenness of the lower surface of semiconductor substrate 1 when semiconductor substrate 1 is mounted on stage 5 and thereby enables an increase in the area of contact and an improvement in the thermal conductivity.

In addition to metals having high thermal conductivity, a nonmetal such as diamond may be used as the main material of stage 5. In the case of using stage 5 that is composed from this type of insulative material, stage 5 cannot be caused to function as an electrostatic chuck electrode, and another method of securing semiconductor substrate 1 onto stage 5 becomes necessary.

FIG. 9 is a schematic sectional view of a semiconductor fabrication device that employs suction as a method of securing semiconductor substrate 1 to stage 5. This semiconductor fabrication device is provided with suction passage 13 having openings on stage 5 at a position that directly underlies semiconductor substrate 1 when semiconductor substrate 1 has been mounted. A suction pump is connected to suction passage 13, and semiconductor substrate 1 can be pulled against and secured to stage 5 by using the suction pump to evacuate the air inside suction passage 13.

The use of this type of suction device in this embodiment is preferable because it enables semiconductor substrate 1 to adhere tightly to stage 1. In other words, the use of a suction device enables semiconductor substrate 1 to be pulled against stage 5 with relatively high strength and produce a tight adhesion, and thus improve the thermal conductivity from semiconductor substrate 1 to stage 5. The use of semiconductor substrate 1 in which the lower surface has been polished to a mirror surface as described hereinabove can further suppress the inflow of gas from gaps between semiconductor substrate 1 and stage 5 and therefore strengthen the suction force to enable a synergistic improvement in thermal conductivity.

A pump that is capable of decreasing the pressure in suction passage 13 to a pressure that is sufficiently lower than the internal pressure of processing chamber 7 during processing is employed as the suction pump used in this suction device, and a turbo-molecular pump, rotary pump, dry pump, or any type of vacuum pump may be used.

(Second Embodiment)

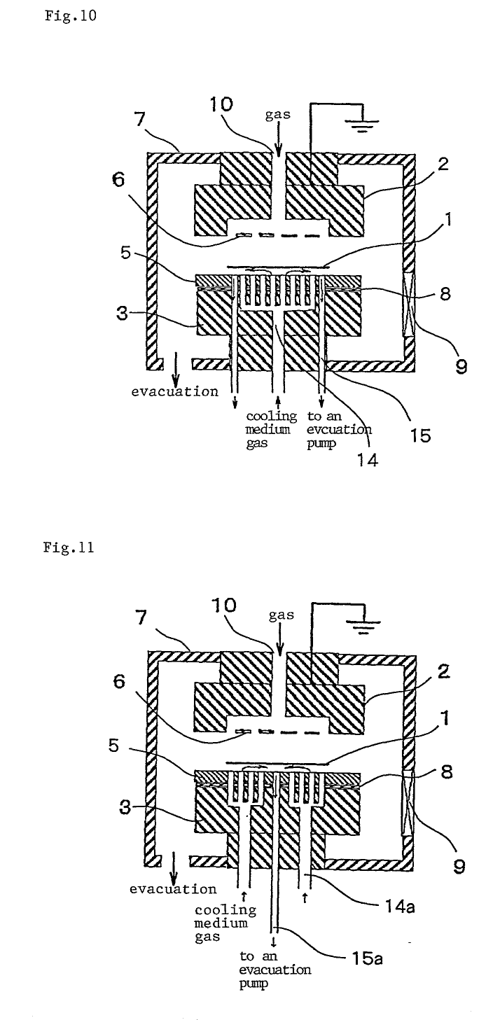

We now refer to FIG. 10, in which is shown a schematic sectional view of the semiconductor fabrication device of the second embodiment of the present invention. In this figure, portions that are equivalent to the first embodiment are given the same reference numerals and redundant explanation is omitted.

This semiconductor fabrication device is provided with cooling medium gas passage 14 having a plurality of openings in the central area of the portion on stage 5 that directly underlies semiconductor substrate 1 when semiconductor substrate 1 is mounted. The semiconductor fabrication device is further provided with first evacuation passages 15 having openings on stage 5 in the peripheral area that is outside cooling medium gas passage 14, and moreover, that is directly below semiconductor substrate 1. An evacuation pump is connected to first evacuation passages 15.

Although this embodiment employs a method in which a cooling medium gas such as helium is directed against the lower surface of semiconductor substrate 1 as the method of cooling semiconductor substrate 1, the embodiment is devised such that the cooling medium gas is not discharged into processing chamber 5 from the periphery of semiconductor substrate 1. In other words, in the semiconductor fabrication device of this embodiment, the cooling medium gas that is introduced from cooling medium gas passage 14 having openings within the central area directly below semiconductor substrate 1 is directed against the lower surface of semiconductor substrate 1 and then flows toward the periphery of semiconductor substrate 1, but before being discharged into processing chamber 7 from the periphery of semiconductor substrate 1, the gas is conducted into first evacuation passages 15 having openings in the peripheral area directly below semiconductor substrate 1 and evacuated.

Because the discharge of cooling medium gas into processing chamber 7 can be suppressed in this embodiment, the occurrence of particles inside processing chamber 7 can also be reduced.

A pump that is capable of decreasing the pressure in first evacuation passages 15 to a pressure that is sufficiently lower than the internal pressure of processing chamber 7 during processing is used as the evacuation pump in the evacuation of cooling medium gas, and any type of vacuum pump such as a turbo-molecular pump, a rotary pump, or a dry pump may be used.

We now refer to FIG. 11 in which is shown a schematic sectional view of a semiconductor fabrication device according to a modification of this embodiment. In this semiconductor fabrication device, first evacuation passage 15a has an opening on stage 5 in the central position of the portion that directly underlies semiconductor substrate 1 when semiconductor substrate 1 is mounted, and cooling medium gas passages 14a have a plurality of openings on stage 5 in the area that surrounds the opening of first evacuation passage 15a. The adoption of this configuration enables cooling by directing cooling medium gas against the area close to the periphery of semiconductor substrate 1.

In this configuration as well, the use of an evacuation pump having sufficient evacuation capability can prevent the discharge of virtually all of the cooling medium gas into processing chamber 7 from the periphery of semiconductor substrate 1. Even though some cooling medium gas may be discharged from the periphery of semiconductor substrate 1, the reduced flow rate of the discharge enables a suppression of the occurrence of particles in processing chamber 7.

(Third Embodiment)

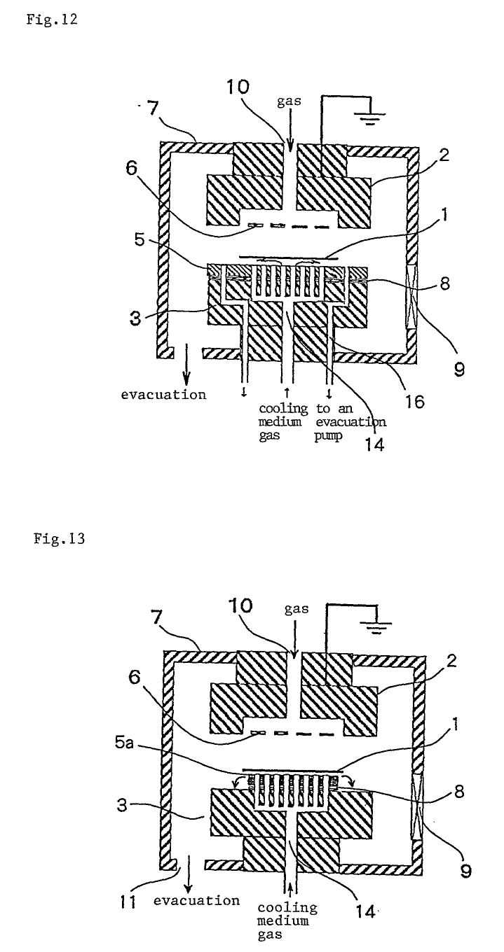

We now refer to FIG. 12, in which is shown a schematic sectional view of the semiconductor fabrication device according to the third embodiment of the present invention. In this figure, portions that are equivalent to the first and second embodiments are identified by the same reference numerals and redundant explanation is omitted.

The semiconductor fabrication device of this embodiment is provided with second evacuation passages 16 having openings on stage 5 that are in the peripheral portion of the upper surface of stage 5, and moreover, that are in an area that is located beyond the edge of semiconductor substrate 1 when semiconductor substrate 1 is mounted.

With this configuration, cooling medium gas that is directed against the lower surface of semiconductor substrate 1 and then discharged into processing chamber 7 from the periphery of semiconductor substrate 1 is drawn toward the openings of second evacuation passages 16, and virtually none of the cooling medium gas flows upward. As a result, the flow of particles that occur inside processing chamber 7 above semiconductor substrate 1 that is caused by the cooling medium gas can be suppressed, and the particles can be prevented from landing on and becoming attached to semiconductor substrate 1.

The present embodiment may also be worked in combination with the second embodiment, whereby a synergistic suppression of the attachment of particles to the semiconductor substrate can be obtained.

(Fourth Embodiment)

We now refer to FIG. 13 in which is shown a schematic sectional view of the semiconductor fabrication device according to the fourth embodiment of the present invention. Parts that are equivalent to the first to third embodiment are identified by the same reference numerals and redundant explanation is omitted.

In the semiconductor fabrication device of this embodiment, stage 5a has an upper surface that is smaller than the semiconductor substrate 1 that is mounted upon it. In other words, stage 5a contacts only the central area of the lower surface of semiconductor substrate 1 when semiconductor substrate 1 is mounted, and the periphery of semiconductor substrate 1 extends beyond stage 5a.

Although the cooling medium gas that is directed against the lower surface of semiconductor substrate 1 is discharged into processing chamber 7 from the periphery of stage 5a in this configuration, the discharged cooling medium gas collides with the portion of semiconductor substrate 1 that protrudes beyond stage 5a, and as a result, virtually none of the cooling medium gas flows above semiconductor substrate 1. Even though particles may occur in processing chamber 7 due to the flow of the cooling medium gas, the particles can be prevented from landing on and becoming attached to semiconductor substrate 1 because the flow of the particles above semiconductor substrate 1 can be impeded.

(Fifth Embodiment)

This embodiment suppresses the occurrence of particles inside the processing chamber in which a semiconductor substrate is processed by appropriately controlling the method of introducing the cooling medium gas that is directed against the lower surface of the semiconductor substrate to cool the semiconductor substrate. The control of the introduction of cooling medium gas in this embodiment is implemented by, for example, a control unit that is incorporated in semiconductor fabrication device control panel 22 shown in FIG. 2.

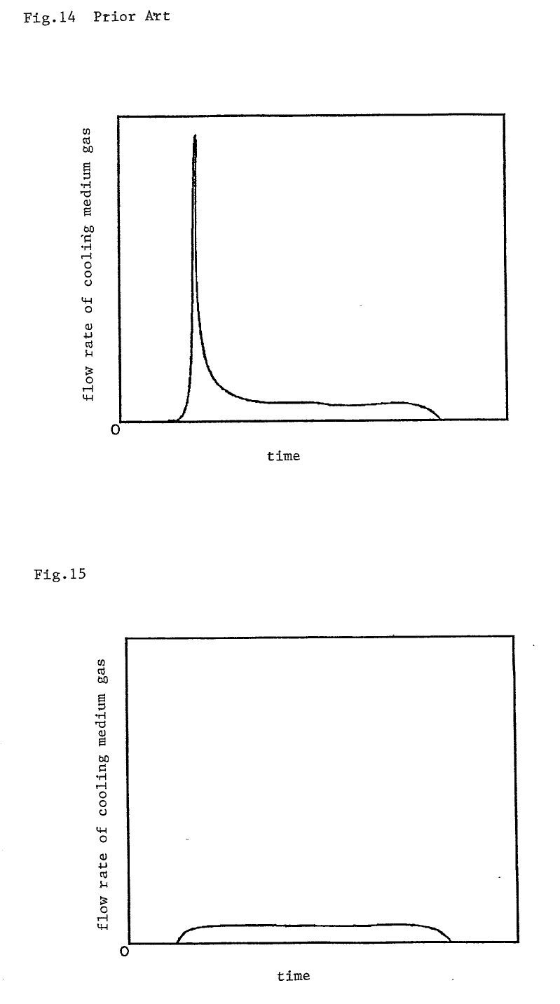

FIG. 14 shows the change in the flow rate over time of the cooling medium gas in a case in which the cooling medium gas is introduced while performing pressure control, which is typically used in semiconductor fabrication devices; and FIG. 15 shows change in the flow rate over time of the cooling medium gas in a case in which the cooling medium gas is introduced by the method of this embodiment.

As described hereinabove, in the prior art, the cooling medium gas was introduced while controlling pressure so as to keep the cooling effect at a definite level. In a case in which the cooling medium gas is introduced with a simple pressure control, the low pressure conditions at the start of introduction causes the pressure correction mechanism such as pressure adjustment valves to allow a high flow rate of the cooling medium gas until the set pressure is attained in order to decrease deviation between the set pressure and the measured pressure. In this case, a high peak tends to occur in the change in the flow rate of the cooling medium gas, as shown in FIG. 14, despite adjustment of the pressure control parameters to cause the change in pressure over time to more smoothly approach the set pressure.

When a large volume of cooling medium gas is introduced in this way, a strong force is applied to deposited films adhering to the stage or to the lower surface of the semiconductor substrate or to extraneous matter that is present here, and a large portion of particles are stirred up inside the processing chamber. It is believed that the particles are agitated by the high flow rate, whereby the particles rise over the semiconductor substrate and easily land on the semiconductor substrate.

Such peaks in the flow rate of the cooling medium gas occur not only immediately following the start of introduction of the cooling medium gas, but may also occur at times of change in the processing conditions of the semiconductor substrate, as described hereinabove, and the inventors of the present invention have actually observed the occurrence of comparatively large numbers of particles inside the processing chamber when such peaks occur.

In the present embodiment, however, cooling medium gas is introduced while implementing flow rate control. As shown in FIG. 15, the adoption of this approach allows the flow rate of the cooling medium gas to increase smoothly until the set flow rate is reached when the cooling medium gas is first introduced, and there is no incidence of peaks in the flow rate as seen when pressure control was used. This approach therefore can reduce the incidence of particles inside the processing chamber that is brought about by the flow of the cooling medium gas. Even when particles do occur inside the processing chamber, the particles are not greatly agitated and therefore are prevented from landing on the semiconductor substrate.

Adequate cooling can be guaranteed despite the use of this flow rate control when introducing the cooling medium gas. A correlation exists between pressure and flow rate of the cooling medium gas when in a steady state, and a cooling effect that is substantially equivalent to a case of employing pressure control can be obtained by setting the flow rate in accordance with this correlation such that the pressure of the cooling medium gas reaches a prescribed pressure at which the desired cooling effect is obtained.

Pressure control and flow rate control may also be combined such that high peaks in the flow rate of the cooling medium gas do not occur. Alternatively, this embodiment may be combined with the second to fourth embodiments, whereby a synergistic improvement can be obtained in suppressing the occurrence of particles inside the processing chamber and the attachment of particles that do occur to the semiconductor substrate.

(Sixth Embodiment)

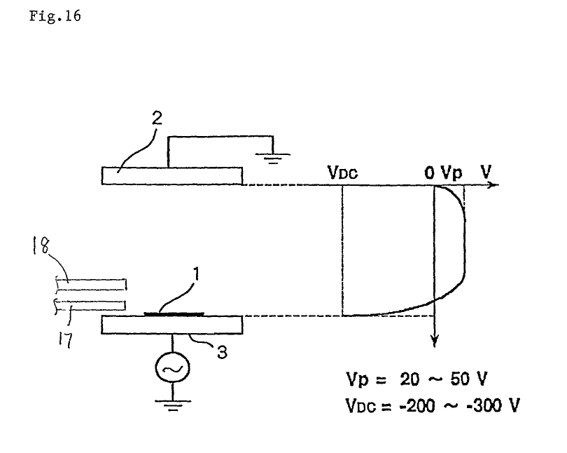

We now refer to FIG. 16, in which is shown a schematic side view of the interior of the processing chamber of the semiconductor fabrication device according to the sixth embodiment of the present invention. This figure shows the general distribution in a vertical direction of the electrostatic potential that occurs when plasma is generated in a typical semiconductor fabrication device that employs plasma. As shown in the figure, the electrostatic potential when generating plasma inside a semiconductor fabrication device that uses plasma is substantially 0 (ground) potential in the vicinity of upper processing electrode 2, which is grounded; a negative potential in the vicinity of lower processing electrode 3, to which a radio-frequency voltage is applied; and a positive potential in the vicinity of the region in which plasma is generated between upper processing electrode 2 and lower processing electrode 3. In a typical semiconductor fabrication device, the maximum value V_{DC} of the negative potential in the vicinity of lower processing electrode 3 is from about −200 to −300 V, and the maximum value V_{P} of the positive potential in the region of plasma generation is from about 20 to 50 V.

As described in the foregoing explanation, this state of the electrostatic potential inside the semiconductor fabrication device during generation of plasma causes particles having a negative charge such as electrons and negative ions to be trapped during plasma generation inside the bulk plasma of positive potential and particles having a positive potential such as positive ions to gather in the vicinity of lower processing electrode 3 and particularly inside the cathode sheath that includes the region of the vicinity of semiconductor substrate 1. Accordingly, particles that are agitated by cooling medium gas during plasma generation are positively charged by the particles of positive potential that are present in great numbers inside the cathode sheath in the vicinity of semiconductor substrate 1.

However, the positively charged particles can be attracted and removed by electrostatic force by providing elimination electrode 17, to which a negative bias potential is applied, next to semiconductor substrate 1. Because a negative self-bias potential occurs on the surface of semiconductor substrate 1 at this time as previously described, the negative bias potential that is applied is preferably a potential that is equal to or greater than the self-bias potential.

When the agitating force of the cooling medium gas is extremely great, particles are stirred up and driven into the bulk plasma. Particles that are taken into the bulk plasma in this way are negatively charged by the particles of negative potential that are present in extremely great numbers in this region, as previously described. Particles that have been negatively charged are trapped between lower processing electrode 3 and upper processing electrode 2 by the previously described electrostatic potential that occurs inside the semiconductor fabrication device. Although it is believed that particles that are trapped in this way not drop during processing of semiconductor substrate 1, the particles may drop when the balance of forces is disrupted by changes in the electrostatic potential that occur when processing conditions change or by the loss of electrostatic potential upon completion of processing.

However, negatively charged particles can be attracted by electrostatic force and eliminated by providing, next to semiconductor substrate 1, elimination electrode 18 to which a positive bias potential is applied.

As described hereinabove, by providing an elimination electrode to which a negative or positive bias potential is applied next to semiconductor substrate 1 in the present embodiment, particles that have been charged to a positive potential or a negative potential can be attracted by electrostatic force to the elimination electrode and removed. In addition, both a first elimination electrode to which a positive bias potential is applied and a second elimination electrode to which a negative potential is applied may be provided.

The present embodiment may also be worked in combination with the second to fifth embodiments, whereby a synergistic improvement can be obtained in suppressing the attachment of particles that occur to the semiconductor substrate.

(Seventh Embodiment)

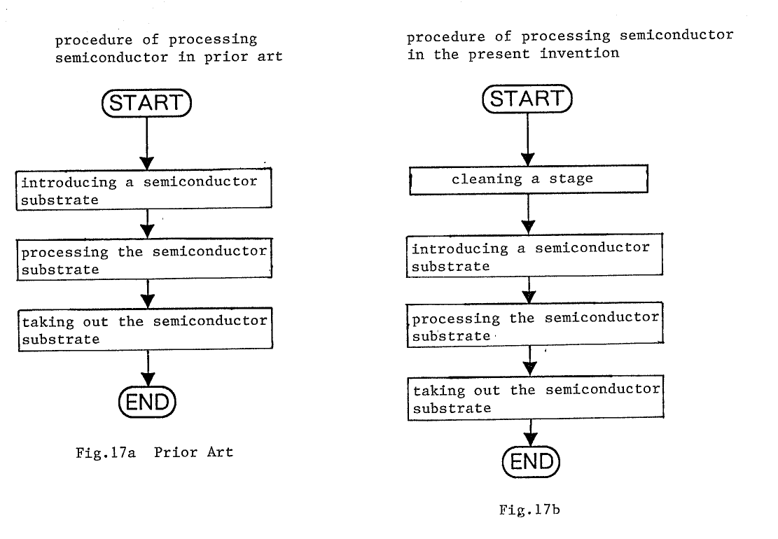

A major portion of the particles that occur in the processing chamber due to the flow of cooling medium gas arise from deposited films that adhere to the stage or from extraneous matter that has fallen and remains on the stage, these particles being produced by being stirred up by the flow of the cooling medium gas. Thus, if processing of a semiconductor substrate is performed according to the prior-art procedure shown in FIG. 17a, the semiconductor substrate is mounted with the stage in a dirty state, and this dirt serves as a source of particles.

The occurrence of particles inside the processing chamber can be reduced by adding, to the prior-art semiconductor substrate processing procedure that is shown FIG. 17a, a step of cleaning the stage before introducing the semiconductor substrate into the processing chamber, as shown in FIG. 17b.

The cleaning of the stage can be carried out by, for example, using the flow of etching components to enable the elimination of deposited films that adhere to the stage and extraneous matter that remains on the stage. As for the method of cleaning that is used in this instance, any method such as normal dry etching, wet etching, or jet scrub may be used, but a method of cleaning that has a potential for introducing new particles is not preferable.

The present embodiment may also be worked in combination with the second to sixth embodiments, whereby a synergistic improvement can be obtained in suppressing the occurrence of particles inside the processing chamber and suppressing the attachment of particles that occur to a semiconductor substrate.

(Eighth Embodiment)

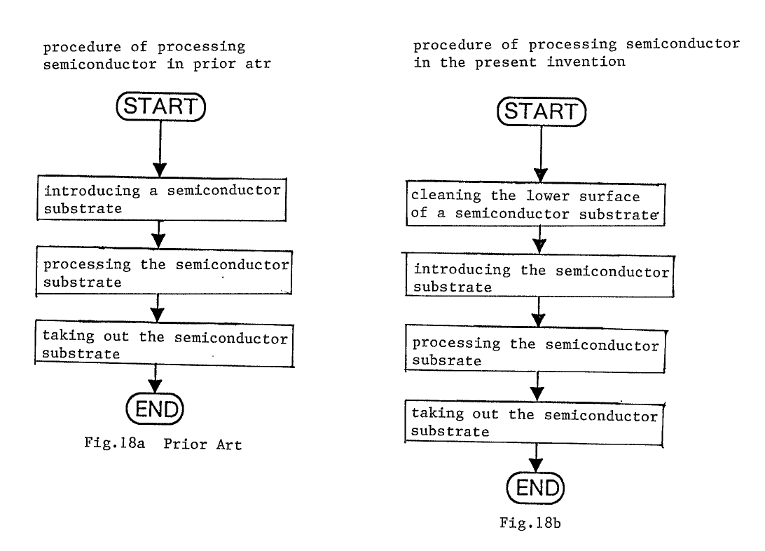

The occurrence of particles inside the processing chamber that is brought about by the flow of cooling medium gas is also caused by the agitation of particles that adhere to the lower surface of the semiconductor substrate by the flow of the cooling medium gas. In other words, when processing of a semiconductor substrate is carried out by the prior-art procedure that is shown in FIG. 18a, the semiconductor substrate is introduced with its lower surface in a dirty state, and this dirt serves as a source of particles.

However, the occurrence of particles in the processing chamber can be reduced by adding, to the semiconductor substrate processing procedure that is shown in FIG. 18a, a step of cleaning the lower surface of the semiconductor substrate before introducing the semiconductor substrate into the processing chamber, as shown in FIG. 18b.

The cleaning of the lower surface of the semiconductor substrate can be implemented by, for example, a cleaning method such as jet scrub, whereby extraneous matter that adheres to the lower surface of the semiconductor substrate can be eliminated. Any method, such as jet scrub, may be employed as the cleaning method in this instance, but a cleaning method having a potential for introducing new particles is not preferable.

Finally, the present embodiment may be worked in combination with the second to seventh embodiment, whereby a synergistic improvement can be obtained in suppressing the occurrence of particles inside the processing chamber and suppressing the attachment of particles that occur to the semiconductor substrate.

While preferred embodiments of the present invention have been described using specific terms, such description is for illustrative purposes only, and it is to be understood that changes and variations may be made without departing from the spirit or scope of the following claims.

What is claimed is:

1. A semiconductor fabrication device comprising:
a processing chamber that can be substantially sealed so as to keep its interior clean; and
a stage that is arranged inside said processing chamber and upon which a semiconductor substrate that is the object of processing is mounted;
wherein said semiconductor fabrication device performs prescribed processes on said semiconductor substrate while cooling said semiconductor substrate on said stage; and
wherein said stage is constituted from a material having high thermal conductivity, and
said semiconductor fabrication device further comprising a cooling medium passage for conducting, only outside the processing chamber, a cooling medium that cools said stage.

2. A semiconductor fabrication device according to claim 1 wherein said stage is constituted from diamond.

3. A semiconductor fabrication device according to claim 1, said semiconductor fabrication device further comprising:
a suction passage having openings in an area of said stage that directly underlies said semiconductor substrate when said semiconductor substrate has been mounted; and
a suction pump connected to said suction passage that is capable of reducing the internal pressure of said suction passage to a pressure that is lower than the internal pressure of said processing chamber during processing.

4. A semiconductor fabrication device comprising:
a processing chamber that can be substantially sealed so as to keep its interior clean; a stage that is arranged inside said processing chamber and upon which a semiconductor substrate that is the object of processing is mounted; and a cooling medium gas passage having openings in the area of said stage that directly underlies said semiconductor substrate when said semiconductor substrate is mounted and into which a cooling medium gas is introduced;
said semiconductor fabrication device further comprising:
a first evacuation passage having openings in an area of said stage that directly underlies said semiconductor substrate when said semiconductor substrate is mounted; and
an evacuation pump that is connected to said first evacuation passage.

5. A semiconductor fabrication device according to claim 4, wherein the openings of said first evacuation passage are opened in a peripheral area of the area of said stage that directly underlies said semiconductor substrate, and the openings of said cooling medium gas passage are opened in a central area that is surrounded by the peripheral area in which said openings of said first evacuation passage are opened.

6. A semiconductor fabrication device comprising:
a processing chamber that can be substantially sealed so as to keep its interior clean; a stage that is arranged inside said processing chamber and upon which a semiconductor substrate that is the object of processing is mounted; and a cooling medium gas passage having openings in the area of said stage that directly underlies said semiconductor substrate when said semiconductor substrate is mounted and into which a cooling medium gas is introduced;
said semiconductor fabrication device further comprising:
a second evacuation passage having openings in a peripheral area of the area of said stage that directly underlies said semiconductor substrate when said semiconductor substrate is mounted; and
an evacuation pump that is connected to said second evacuation passage.

7. A semiconductor fabrication device comprising:
a processing chamber that can be substantially sealed so as to keep its interior clean; a stage that is arranged inside said processing chamber and upon which a semiconductor substrate that is the object of processing is mounted; and a cooling medium gas passage having openings in the area of said stage that directly underlies said semiconductor substrate when said semiconductor substrate is mounted and into which a cooling medium gas is introduced;
wherein the upper surface of said stage is smaller than said semiconductor substrate.

8. A semiconductor fabrication device comprising:
a processing chamber that can be substantially sealed so as to keep its interior clean; a stage that is arranged inside said processing chamber and upon which a semiconductor substrate that is the object of processing is mounted; and a cooling medium gas passage having openings in the area of said stage that directly underlies said semiconductor substrate when said semiconductor substrate is mounted and into which a cooling medium gas is introduced; said semiconductor fabrication device further comprising:
an introduction control means for introducing said cooling medium gas such that its flow rate does not exceed a prescribed flow rate.

9. A semiconductor fabrication device according to claim 8 wherein said introduction control means controls flow rate.

10. A semiconductor fabrication device comprising:
a processing chamber that can be substantially sealed so as to keep its interior clean;
a processing gas introduction means for introducing processing gas into said processing chamber;
a lower processing electrode that is arranged in the lower portion of said processing chamber and an upper processing electrode that is arranged in the upper portion of said processing chamber to confront said lower processing electrode for supplying electrical power to convert said processing gas to plasma;
a stage that is arranged above said lower processing electrode and upon which a semiconductor substrate that is the object of processing is mounted; and
a cooling medium gas passage having openings in the area of said stage that directly underlies said semiconductor substrate when said semiconductor substrate is mounted and into which a cooling medium gas is introduced;
said semiconductor fabrication device further comprising an elimination electrode that is positioned in the vicinity of said semiconductor substrate when said semiconductor substrate is mounted on said stage and to which a direct-current power supply is connected.

11. A semiconductor fabrication device according to claim 10, wherein a negative voltage is applied to said elimination electrode.

12. A semiconductor fabrication device according to claim 10, wherein a positive voltage is applied to said elimination electrode.

13. A semiconductor fabrication device according to claim 10, comprising:
a first said elimination electrode to which a negative voltage is applied; and
a second said elimination electrode to which a positive voltage is applied.

14. A semiconductor fabrication method that uses a semiconductor fabrication device comprising a processing chamber that can be substantially sealed so as to keep its interior clean and a stage that is arranged inside said processing chamber and upon which a semiconductor substrate that is the object of processing is mounted; said semiconductor fabrication method comprising a step of:
giving a mirror-surface polishing treatment to the lower surface of said semiconductor substrate before mounting said semiconductor substrate on said stage.

15. A semiconductor fabrication method that uses a semiconductor fabrication device comprising a processing chamber that can be substantially sealed so as to keep its interior clean and a stage that is arranged inside said processing chamber and upon which a semiconductor substrate that is the object of processing is mounted;
said semiconductor fabrication method comprising a step of:
cleaning said stage before said semiconductor substrate is mounted on said stage.

16. A semiconductor fabrication method that uses a semiconductor fabrication device comprising a processing chamber that can be substantially sealed so as to keep its interior clean and a stage that is arranged inside said processing chamber and upon which a semiconductor substrate that is the object of processing is mounted;
said semiconductor fabrication method comprising a step of:
cleaning the lower surface of said semiconductor substrate before said semiconductor substrate is mounted on said stage.
